(19) United States
(12) Patent Application Publication
(10) Pub. No.: US 2024/0110944 A1
(43) Pub. Date: Apr. 4, 2024

(54) Electrical Circuits Testing Device and Method of Use

(71) Applicant: Milton Solis, Hollywood, FL (US)

(72) Inventor: Milton Solis, Hollywood, FL (US)

(21) Appl. No.: 18/185,713

(22) Filed: Mar. 17, 2023

Related U.S. Application Data
(60) Provisional application No. 63/412,977, filed on Oct. 4, 2022.

(51) Int. Cl. G01R 1/067

(52) U.S. Cl. CPC G01R 1/06788; G01R 1/0675; G01R 31/005

(57) ABSTRACT

The present invention relates to a portable testing device for checking power and ground of electrical circuits of automotive and marine vehicles, while obviating the need of a power probe or a meter. The device features a banana jack having a female connector and a test light having a strobe. A plurality of adapters including at least a back probing clip, a back piercing clip, and an alligator clip are provided with the device, wherein the female connector is configured to removably receive and accommodate an adapter. The strobe and the adapter attached to the banana jack are connected to a circuit and a ‘good’ circuit is indicated by illumination of an LED bulb disposed inside the test light. The device allows the users to easily test power and ground across two wires by either back probing using the back probing clip, or piercing using the back piercing clip.

### CROSS-REFERENCE TO RELATED APPLICATION

The present application claims priority to, and the benefit of, U.S. Provisional Application No. 63/412,977, which was filed on Oct. 4, 2022, and is incorporated herein by reference in its entirety.

### FIELD OF THE INVENTION

The present invention relates generally to the field of circuit testing devices. More specifically, the present invention relates to a redesigned circuit testing light device for checking electrical circuits of automotive and marine vehicles. The device has a banana jack for receiving an adapter from a plurality of interchangeable adaptors, including back probing clips, back piercing clips, and alligator clips. A test light illuminates to indicate a ‘good’ circuit when a strobe of the test light and adapter attached to the banana jack are connected to a circuit or wiring assembly. Accordingly, the present disclosure makes specific reference thereto. Nonetheless, it is to be appreciated that aspects of the present invention are also equally applicable to other like applications, devices, and methods of manufacture.

### BACKGROUND

By way of background, there are three main types of automotive electrical circuits: power, ground, and signal. The power circuit supplies electricity to all the other circuits in the car. The ground circuit provides a path for electricity to flow back to the battery. It is a duty of an automotive technician to check these circuits and to identify malfunctions. When one of these circuits malfunction, it can cause problems with the car's performance or even create a fire hazard. Technicians generally use test meters and probing devices in the form of a circuit tester for making electrical tests of these circuits. Electrical testers are useful to check for voltage, continuity, shorted or open circuits, and improper wiring.

Conventionally, multimeters are used for checking voltage level and additional power probes are used by technicians. A correct voltage scale such as from 0 to 20 volts is set on the multimeter and is used along with a battery terminal for checking circuits. Pocket screwdrivers are used by technicians during checking of circuits. Carrying and using power probes or meters is not only cumbersome and time consuming, but is difficult to set-up in hard-to-reach areas.

Piercing kits, including probing and piercing clips, are commonplace in automotive vehicles. People are further accustomed to using them without need of any professional help. People desire improved circuit testing devices that can effectively and easily check automotive circuits without needing of a power probe or meter.

Therefore, there exists a long-felt need in the art for an improved circuit testing device for marine and automotive vehicles. There is also a long-felt need in the art for a circuit testing device that eliminates use of pocket screwdrivers into female connectors of a circuit or wiring assembly to check power and ground. Additionally, there is a long-felt need in the art for a testing device for automotive circuits that does not require a power probe or a meter such as a multimeter. Moreover, there is a long-felt need in the art for an automotive circuit testing device that is easy to use and can reach hard-to-reach areas. Further, there is a long-felt need in the art for a circuit testing device that can use and accommodate back probing clips, back piercing clips, and alligator clips. Finally, there is a long-felt need in the art for an improved testing device for checking power and ground on a known ‘good’ or loaded circuit, and without the need of a power probe or a meter.

The subject matter disclosed and claimed herein, in one embodiment thereof, comprises a portable testing device for checking power and ground on a known ‘good’ or loaded circuit of an automotive or marine vehicle, while obviating the need of a power probe or a meter. The device further comprising a banana jack wire having two opposite ends, a banana jack attached to the first end of the wire, a test light integrated to the opposite end of the wire, a plurality of piercing and probing adapters, the adapters including at least a back probing clip, a back piercing clip, and an alligator clip, wherein the banana jack has a female connector configured to removably receive and accommodate an adapter for testing a circuit. The test light has a strobe, wherein the strobe and the adapter attached to the banana jack connect to the circuit and a ‘good’ circuit is indicated by illumination of an LED bulb disposed inside the test light.

In this manner, the automotive vehicle electrical circuits testing device of the present invention accomplishes all of the forgoing objectives and provides users with a portable device to vet power with, for example, leads, connectors, lines or wires and ground of electrical circuits without needing a power probe or meter. Interchangeable adaptors, including back probing clips, back piercing clips, and alligator clips can be added to eliminate use of pocket screwdrivers. Illumination of a test light easily indicates a ‘good’ circuit and offers a quick and convenient check. The device provides ease and convenience to marine and automotive technicians everywhere.

### SUMMARY OF THE INVENTION

The following presents a simplified summary in order to provide a basic understanding of some aspects of the disclosed innovation. This summary is not an extensive overview, and it is not intended to identify key/critical elements or to delineate the scope thereof. Its sole purpose is to present some general concepts in a simplified form as a prelude to the more detailed description that is presented later.

The subject matter disclosed and claimed herein, in one embodiment thereof, comprises a portable testing device for checking power and ground on a known ‘good’ or loaded circuit, and without the need of a power probe or a meter. The device further comprising a wire having two opposite ends, a banana jack attached to the first end of the wire, a test light integrated to the opposite end of the wire, a plurality of piercing and probing adapters, the adapters including at least a back probing clip, back piercing clip, and alligator clips, wherein the banana jack has a female connector configured to removably receive and accommodate an adapter. The test light has a strobe, wherein the strobe and the adapter attached to the banana jack connect to a circuit and a ‘good’ circuit is indicated by illumination of an LED bulb disposed inside the test light. The device allows the users to easily test power and ground across two wires by either back probing or piercing, which was not possible with conventional test light devices.

In a further embodiment of the present invention, a circuit testing light device configured to vet power and ground is disclosed. The device features, for example, a five-foot PU wire having a banana jack and a test light disposed on opposite ends thereof, a plurality of adapters including at least a back probing clip, a back piercing clip, and an alligator clip, the banana jack is configured to receive an adapter, wherein the connected adapter and a strobe of the test light are used for checking power and ground of a circuit. The test light includes a resistor whose resistance changes for illuminating an LED disposed inside the test light for indicating a ‘good’ circuit.

In a further embodiment of the present invention, a method of testing a wiring assembly for determining if the assembly is ‘good or bad’ is described. The method includes the steps of: providing a testing device, the device having a banana lead jack, a plurality of interchangeable adapters, a test light having an LED bulb disposed therein; attaching an adapter into a female connector of the banana lead jack; connecting the adapter and a strobe of the test light to a circuit; and, automatically, illuminating an LED bulb for indicating an electrically sound circuit or indicating a ‘bad’ or short circuit when the LED bulb is not illuminated.

Numerous benefits and advantages of this invention will become apparent to those skilled in the art to which it pertains upon reading and understanding of the following detailed specification.

To the accomplishment of the foregoing and related ends, certain illustrative aspects of the disclosed innovation are described herein in connection with the following description and the annexed drawings. These aspects are indicative, however, of but a few of the various ways in which the principles disclosed herein can be employed and are intended to include all such aspects and their equivalents. Other advantages and novel features will become apparent from the following detailed description when considered in conjunction with the drawings.

### BRIEF DESCRIPTION OF THE DRAWINGS

The description refers to provided drawings in which similar reference characters refer to similar parts throughout the different views, and in which:

FIG. 1 illustrates a standalone view of a circuit testing light device of the present invention in accordance with the disclosed architecture;

FIG. 2 illustrates a perspective view of the testing device with a testing strobe releasably attached to a banana jack for use to test a circuit in accordance with the disclosed architecture;

FIG. 3 illustrates an enlarged view of the testing device of the present invention being set up on a vehicle to test an automotive circuit in accordance with the disclosed architecture;

FIG. 4 illustrates an enlarged view of the banana jack of the circuit testing device of the present invention in accordance with the disclosed architecture;

FIG. 5 illustrates an enlarged view of the circuit testing device of the present invention with a back piercing clip testing a circuit setup in accordance with the disclosed architecture; and

FIG. 6 illustrates an enlarged view of the test light of the testing device of the present invention in accordance with the disclosed architecture.

### DETAILED DESCRIPTION OF THE PRESENT INVENTION

The innovation is now described with reference to the drawings, wherein like reference numerals are used to refer to like elements throughout. In the following description, for purposes of explanation, numerous specific details are set forth in order to provide a thorough understanding thereof. It may be evident, however, that the innovation can be practiced without these specific details. In other instances, well-known structures and devices are shown in block diagram form in order to facilitate a description thereof. Various embodiments are discussed hereinafter. It should be noted that the figures are described only to facilitate the description of the embodiments. They are not intended as an exhaustive description of the invention and do not limit the scope of the invention. Additionally, an illustrated embodiment need not have all the aspects or advantages shown. Thus, in other embodiments, any of the features described herein from different embodiments may be combined.

As noted above, there is a long-felt need in the art for an improved circuit testing device for marine and automotive vehicles. There is also a long-felt need in the art for circuit testing device that eliminates use of pocket screwdrivers into female connectors of a circuit or wiring assembly to check power and ground. Additionally, there is a long-felt need in the art for a testing device for automotive circuits that does not require a power probe or a meter such as a multimeter. Moreover, there is a long-felt need in the art for an automotive circuit testing device that is easy to use and can reach hard-to-reach areas. Further, there is a long-felt need in the art for a circuit testing device that can use back probing clips, back piercing clips, and alligator clips. Finally, there is a long-felt need in the art for an improved testing device for checking power and ground on a known ‘good’ or loaded circuit, and without the need of a power probe or a meter.

The present invention, in one exemplary embodiment, is a method of testing into a wiring assembly for determining if the assembly is ‘good’ or bad. The method includes the steps of providing a testing device, the device having a banana lead jack, a plurality of interchangeable adapters, a test light having an LED bulb disposed therein; attaching an adapter into a female connector of the banana lead jack; connecting the adapter and a strobe of the test light to a circuit; and, automatically illuminating the LED bulb for indicating an electrically sound circuit else indicating a bad or short circuit in case the LED bulb is not illuminated.

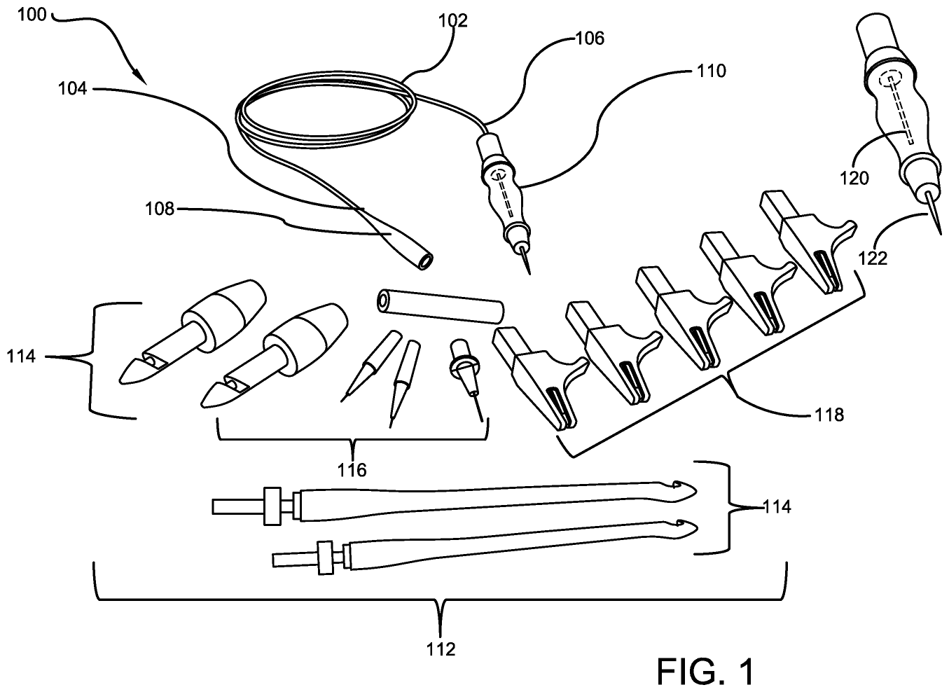

Referring initially to the drawings, FIG. 1 illustrates a standalone view of a circuit testing light device of the present invention in accordance with the disclosed architecture. The device 100 of the present invention is designed to vet power and ground of different types of automotive circuits and can be used by marine and automotive technicians. The device 100 features a copper or silicone wire 102 having two opposite ends 104, 106. The first end 104 has a banana lead jack 108 and the second end 106 has a test light 110. The jack 108 and the test light 110 are integrally attached to the wire 102 for making a closed and integrated circuit.

The banana lead jack 108 is configured to be compatible to removably receive automotive test lead kit piercing and probing clips 112 for effectively performing automotive circuit testing. The set of clips 112 includes at least one or more back probing clips 114, one or more back piercing clips and strobes 116, and/or one or more alligator clips 118. An automotive operator can easily switch the clips while testing a circuit thereby eliminating use of pocket screwdrivers. The lead jack 108 and the test light 110 can be used with any circuit for testing a wiring assembly or a circuit.

The test light component 110 is configured to work with 12V and has a built in LED bulb 120 for high visibility and long life. The bulb 120 illuminates when shorts/breaks in an electrical circuit is detected. The test light 110 has a special shell, mini size, durable ABS material, heat-resistant, and high-tensile strength. The testing device 100 is portable, compact, lightweight and can be carried easily. The test light component 110 has a sharp stainless-steel probe 122 to work with any automotive component, including but not limited to, fuel injector, spark plugs, crankshaft sensors, and more. The sharp stainless-steel probe 122 can have a length of about four inches and the test light 110 can have a length of about six inches to reach hard-to-reach narrow areas.

The electric circuit testing device 100 can work in a range of about 5V to about 30V in different embodiments, preferably for 12V supply in automotive and marine vehicles, and can be used as a DC voltage tester, car fuse tester, automotive battery tester, and probe tester. The device 100 can be used for a variety of cars, trailers, vans, RVs, motorcycles, boats, etc. The wire 102 can have a length from about 47 inches to about 72 inches and provides heat insulation, wear resistance, and tensile strength to the test light for use with, for example, an automobile.

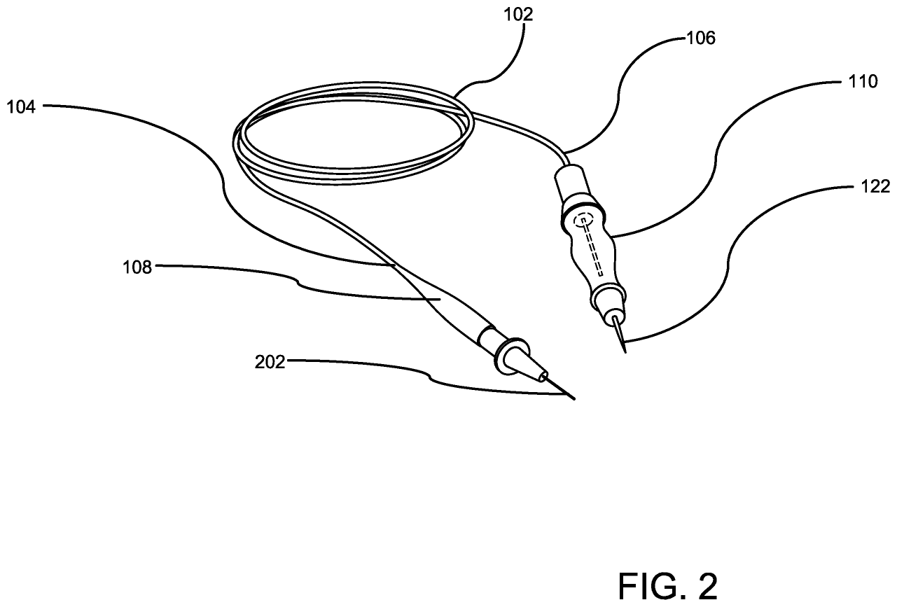

FIG. 2 illustrates a perspective view of the testing device 100 with a testing strobe releasably attached to the banana jack for use to test a circuit in accordance with the disclosed architecture. As illustrated, a testing strobe 202 which can be any of the piercing or probing clips as illustrated in FIG. 1 can be releasably fastened to the banana jack 108. The testing strobe 202 is manually fastened to the jack 108 allowing an electric connection with the tester 110 along the wire 102. The probes 202, 122 can be used with any circuit or wiring assembly in an automotive vehicle for testing ground and integrity of the circuits. The test light 110 may be connected to a positive end of the circuit and the probe 202 can be connected to the ground wire for checking ground integrity of the circuit. The device 100 can also be used for testing positive voltage of the circuit as well. It should be noted that any conventional testing adapters can be detachably fastened to the banana jack 108 as per preference and requirement of the user.

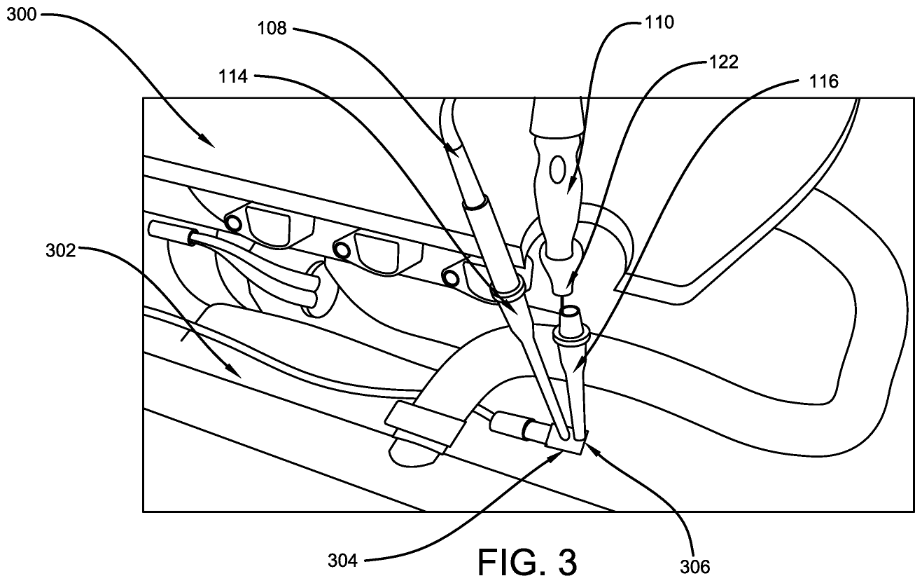

FIG. 3 illustrates an enlarged view of the testing device of the present invention being set up on a vehicle to test an automotive circuit in accordance with the disclosed architecture. The device 100 in the present embodiment is set up in the engine 302 of a vehicle 300 with a back probing clip 114 releasably attached to the banana jack 108 and a back piercing clip 116 releasably attached to the strobe 122 of the test light 110. The clips 114, 116 are attached to the ground wire (or negative pin) 304 and positive pin 306, respectively. The bulb 120 illuminates when the ground integrity is ‘good’ and it should be appreciated that the device 100 eliminates the use of any power probe to add to a power source or use of a meter such as a multimeter.

The clips can be removed and replaced by different types of other clips as per requirements of the testing and design of the circuit or wiring assembly. Further, the LED bulb 120 can also be replaced if malfunctioned. The device 100 can reach hard-to-reach areas within the engine 302 allowing users to effectively test for ground integrity of the circuits.

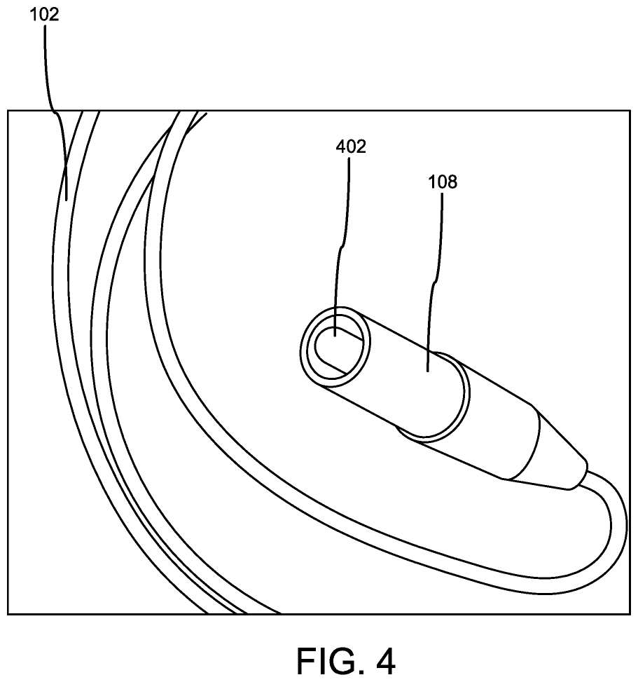

FIG. 4 illustrates an enlarged view of the banana jack of the circuit testing device of the present invention in accordance with the disclosed architecture. The banana jack 108 has a female connector 402 for receiving a male connector of piercing and probing adapters shown in FIG. 1. The female connector 402 is configured to provide an electrical connection of a clip attached to the connector 402 with the test light 110 positioned on an opposite end of the wire 102. The banana jack 108 is flexible and is compatible with conventional piercing kits. The banana jack 108, using the female connector 402, allows operators to easily test power and ground across two wires by either back probing or piercing which is not possible with conventional circuit test-light products. The banana jack 108 can be made of one of silicone, PU, or any other flexible and fire-resistant material.

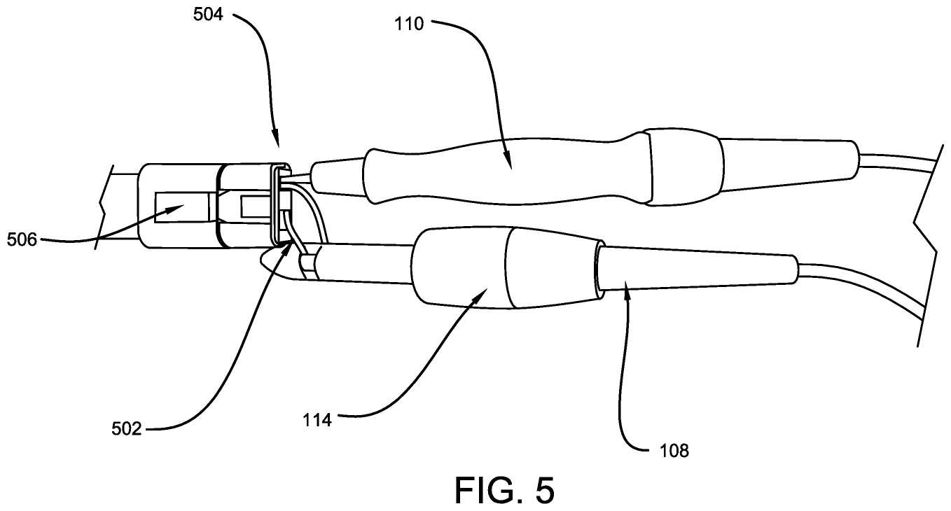

FIG. 5 illustrates an enlarged view of the circuit testing device of the present invention with a back piercing clip testing a circuit setup in accordance with the disclosed architecture. As illustrated, a back piercing clip 114 is attached to the female connector 402 of jack 108 such that the clip 114 easily pierces a wire 502 and thereby obviating the need of any pocket screwdriver. The stainless-steel strobe 122 is inserted to the opposite end 504 of the circuit/sensor 506 allowing an operator to check the circuit 506 without any power device or meter. The LED 120 illuminates for indicating to the operator about functioning of the circuit 506. In situations where the LED 120 does not illuminate or fluctuates, then, the circuit 506 may be malfunctional.

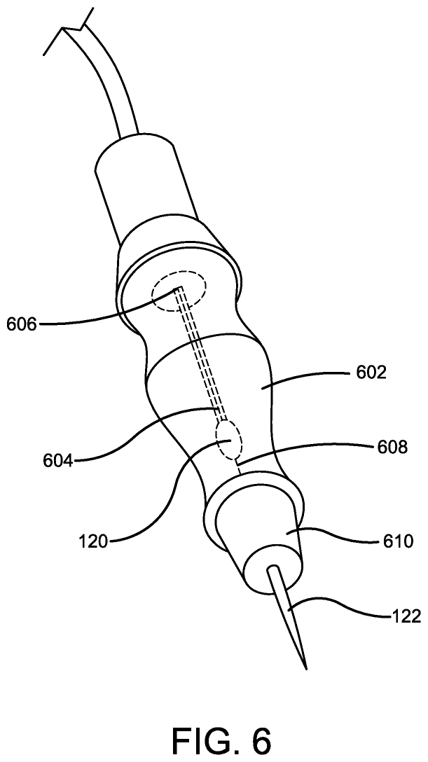

FIG. 6 illustrates an enlarged view of the test light of the testing device of the present invention in accordance with the disclosed architecture. The test light 108 has a transparent body 602 allowing a user to view the LED 120 indicating status of circuit being tested by the device 100. A resistor 608 is positioned along the LED 120 wherein resistance of the resistor 608 changes when strobe 122 makes contact with a circuit. An insulating stem 610 is positioned at the distal end of the strobe 122 for protecting an operator from the electric current. A spring 604 connects the LED 120 with an earthing point 606 wherein the connection provides a ‘good’ ground integrity of a circuit system.

Certain terms are used throughout the following description and claims to refer to particular features or components. As one skilled in the art will appreciate, different persons may refer to the same feature or component by different names. This document does not intend to distinguish between components or features that differ in name but not structure or function. As used herein “electric circuit testing device”, “testing device”, “automotive circuits testing device”, and “device” are interchangeable and refer to the electric circuit testing device 100 of the present invention.

Notwithstanding the forgoing, the electric circuit testing device 100 of the present invention can be of any suitable size and configuration as is known in the art without affecting the overall concept of the invention, provided that it accomplishes the above-stated objectives. One of ordinary skill in the art will appreciate that glass shell with the electric circuit testing device 100 as shown in the FIGS. are for illustrative purposes only, and that many other sizes and shapes of the electric circuit testing device 100 are well within the scope of the present disclosure. Although the dimensions of the electric circuit testing device 100 are important design parameters for user convenience, the electric circuit testing device 100 may be of any size that ensures optimal performance during use and/or that suits the user's needs and/or preferences.

Various modifications and additions can be made to the exemplary embodiments discussed without departing from the scope of the present invention. While the embodiments described above refer to particular features, the scope of this invention also includes embodiments having different combinations of features and embodiments that do not include all of the described features. Accordingly, the scope of the present invention is intended to embrace all such alternatives, modifications, and variations as fall within the scope of the claims, together with all equivalents thereof.

What has been described above includes examples of the claimed subject matter. It is, of course, not possible to describe every conceivable combination of components or methodologies for purposes of describing the claimed subject matter, but one of ordinary skill in the art may recognize that many further combinations and permutations of the claimed subject matter are possible. Accordingly, the claimed subject matter is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A circuit testing light device for vetting power and ground of circuits, the circuit testing light device comprising:
a connecting wire between a first end and a second end;
wherein said first end having a banana lead jack and said second end having a test light;
wherein said banana lead jack and said test light integrally attached at opposing ends to said connecting wire for making a closed and integrated circuit; and
further wherein said banana lead jack selectively receives a test lead selected from a group of consisting of a back probing clip, a back piercing clip, and an alligator clip.

2. The circuit testing light device of claim 1, wherein said back piercing clip having a testing strobe.

3. The circuit testing light device of claim 2, wherein said test light having a built in LED bulb for illumination upon detecting a ‘good’ electrical circuit.

4. The circuit testing light device of claim 3, wherein said test light having a shell, including an ABS material.

5. The circuit testing light device of claim 4, wherein said ABS material having heat resistance.

6. The circuit testing light device of claim 3, wherein said test light having a stainless-steel probe for making contact with an automotive component.

7. The circuit testing light device of claim 6, wherein said automotive component selected from a group consisting of a fuel injector, a spark plug, and a crankshaft sensor.

8. The circuit testing light device of claim 7, wherein said stainless-steel probe having a length of about four inches.

9. The circuit testing light device of claim 8, wherein said test light having a length of about six inches.

10. The circuit testing light device of claim 9, wherein said connecting wire selected from a silicone wire and a copper wire.

11. The circuit testing light device of claim 10, wherein said circuits are selected from automotive circuits and marine circuits.

12. The circuit testing light device of claim 11, wherein said circuit testing light device having a range of about 5V to about 30V.

13. The circuit testing light device of claim 12, wherein said electric circuit testing device used as a tester of devices selected from a group consisting of a DC voltage device, a car fuse device, an automotive battery device, and a probe tester device.

14. The circuit testing light device of claim 13, wherein said connecting wire having a length from about 47 inches to about 72 inches.

15. A circuit testing light device for vetting power and ground of circuits, the circuit testing light device comprising:
a circuit testing light device having a connecting wire between a first end and a second end;
wherein said first end having a banana lead jack and said second end having a test light;
wherein said banana lead jack and said test light integrally attached at opposing ends to said connecting wire for making a closed and integrated circuit;
wherein said banana lead jack selectively receives a test lead selected from a group of consisting of a back probing clip, a back piercing clip, and an alligator clip;
wherein said test light connected to a positive end of a circuit and said test lead connected to a ground wire for checking integrity and positive voltage of the circuit;
wherein said test light having a stainless-steel probe for making contact with an automotive component;
wherein said automotive component selected from a group consisting of a fuel injector, a spark plug, and a crankshaft sensor; and
further wherein said stainless-steel probe having a length of about four inches.

16. The circuit testing light device of claim 15, wherein said circuit testing light device having a range of about 5V to about 30V.

17. The circuit testing light device of claim 16, wherein said electric circuit testing device used as a tester of devices selected from a group consisting of a DC voltage device, a car fuse device, an automotive battery device, and a probe tester device.

18. A method for vetting power and ground of circuits, the method comprising the steps of:
providing a circuit testing light device for vetting power and ground of circuits wherein said circuit testing light device having a connecting wire between a first end and a second end;
connecting a banana lead jack to said first end and connecting a test light to said second end;
integrally attaching said banana lead jack and said test light at opposing ends to said connecting wire for making a closed and integrated circuit;
selectively inserting a test lead from a plurality of test leads into said banana lead jack, wherein said test lead selected from a group consisting of a back probing clip, a back piercing clip, and an alligator clip;
connecting said test light to a positive end of a circuit;
connecting said test lead to a ground wire for checking integrity and positive voltage of the circuit; and
contacting a stainless-steel probe of said test light with the circuit of an automotive component.

19. The method of vetting power and ground of circuits of claim 18, wherein said electric circuit testing device used as a tester of devices selected from a group consisting of a DC voltage device, a car fuse device, an automotive battery device, and a probe tester device.

20. The method of vetting power and ground of circuits of claim 19, wherein said banana lead jack having a female connector for receiving a male connector of said test lead.
